(19) United States
(12) Patent Application Publication
(10) Pub. No.: US 2013/0048350 A1
(43) Pub. Date: Feb. 28, 2013

(54) BASE MEMBER

(71) Applicants: Michio Horiuchi, Nagano-shi (JP); Yasue Tokutake, Nagano-shi (JP); Yuichi Matsuda, Nagano-shi (JP)

(72) Inventors: Michio Horiuchi, Nagano-shi (JP); Yasue Tokutake, Nagano-shi (JP); Yuichi Matsuda, Nagano-shi (JP)

(73) Assignee: SHINKO ELECTRIC INDUSTRIES CO., LTD., Nagano-shi (JP)

(21) Appl. No.: 13/588,013

(22) Filed: Aug. 17, 2012

(30) Foreign Application Priority Data
Aug. 26, 2011 (JP) 2011-185134

(51) Int. Cl. H05K 1/05

(52) U.S. Cl. 174/255

(57) ABSTRACT

A base member includes: a core layer including: a plate-like body, made of aluminum oxide; and plural linear conductors, which penetrate through the plate-like body in a thickness direction of the plate-like body; a bonding layer, formed on at least one of a first surface and a second surface of the core layer; and a silicon layer or a glass layer, formed on the bonding layer.

### BACKGROUND

1. Field of the Invention

The present invention relates to a base member from which a wiring substrate is manufactured.

2. Description of the Related Art

Among conventional base members from which wiring substrates are manufactured are a silicon plate and a glass plate. A wiring substrate is manufactured by forming through-holes through a silicon plate or a glass plate (base member), filling the through-holes with a conductive material, and forming insulating layers and wiring layers one on another on a resulting structure, as disclosed in JP-A-2005-72596.

Another type of base member may be used in which many linear conductors formed by forming through-holes having a very small diameter at a high density by, for example, anodic oxidation, so that they penetrate through a plate made of an insulative material such as an inorganic dielectric (e.g., alumina (aluminum oxide)) in its thickness direction and filling the through-holes with metal are arranged at a high density.

However, the process of forming through-holes through a silicon plate or a glass plate and filling the through-holes with a conductive material cannot be carried out easily and hence causes such problems as reduction in throughput and increase in manufacturing cost.

Although the processing time can be shortened by thinning a silicon plate or a glass plate, such a base member is insufficient in mechanical strength and hence difficult to handle, resulting in, for example, a problem that a crack may develop therein while it is transported or handled in a manufacturing process.

Since many linear conductors are formed at a high density in the above-mentioned base member, and the mechanical strength thereof is insufficient, the base member is difficult to handle, like a thinned silicon plate or glass plate. Consequently, a problem may be occurred, for example, a crack appears therein while it is transported or handled in a manufacturing process.

### SUMMARY

The present invention has been made in view of the above problems, and an object of the invention is therefore to provide a base member which is higher in mechanical strength than conventional ones.

A base member according to one aspect of the invention includes: a core layer including: a plate-like body, made of aluminum oxide; and plural linear conductors, which penetrate through the plate-like body in a thickness direction of the plate-like body; a bonding layer, formed on at least one of a first surface and a second surface of the core layer; and a silicon layer or a glass layer, formed on the bonding layer.

A base member according to another aspect of the invention includes: a core layer including: a plate-like body, made of aluminum oxide; and plural linear conductors, which penetrate through the plate-like body in a thickness direction of the plate-like body; and a first wiring layer, which is electrically connected to part of the plural linear conductors, and is formed on at least one of a first surface and a second surface of the core layer; an insulating layer, covering the first wiring layer; a second wiring layer, electrically connected to the first wiring layer by lines formed through the insulating layer; a bonding layer, covering the second wiring layer; and a silicon layer or a glass layer, formed on the bonding layer.

A base member according to a still another aspect of the invention includes: a core layer including: a plate-like body, made of aluminum oxide; and plural linear conductors, which penetrate through the plate-like body in a thickness direction of the plate-like body; and a glass layer, formed on at least one of a first surface and a second surface of the core layer.

The above configurations make it possible to provide a base member which is higher in mechanical strength than conventional ones.

### BRIEF DESCRIPTION OF THE DRAWINGS

The present invention will become more fully understood from the detailed description given hereinbelow and the accompanying drawing which is given by way of illustration only, and thus is not limitative of the present invention and wherein:

FIG. 1 is a sectional view of a base member according to a first embodiment;

FIG. 2 is a first sectional view illustrating a manufacturing process of the base member according to the first embodiment;

FIG. 3 is a second sectional view illustrating the manufacturing process of the base member according to the first embodiment;

FIG. 4 is a third sectional view illustrating the manufacturing process of the base member according to the first embodiment;

FIG. 5 is a fourth sectional view illustrating the manufacturing process of the base member according to the first embodiment;

FIG. 6 is a sectional view of a base member according to a first modification of the first embodiment;

FIG. 7 is a sectional view of a base member according to a second modification of the first embodiment;

FIG. 8 is a sectional view of a base member according to a second embodiment;

FIG. 9A is a sectional view of a base member according to a first modification of the second embodiment;

FIG. 9B is a partial plan view of the base member according to the first modification of the second embodiment;

FIG. 10 is a sectional view of a base member according to a second modification of the second embodiment;

FIG. 11 is a sectional view of a base member according to a third modification of the second embodiment;

FIG. 12 is a sectional view of a base member according to a third embodiment;

FIG. 13 is a sectional view of a wiring substrate which uses the base member according to the third embodiment;

### DETAILED DESCRIPTION OF THE INVENTION

Modes for carrying out the present invention will be hereinafter described with reference to the drawings. The same constituent elements are given the same reference symbol in the drawings, and may not be described redundantly.

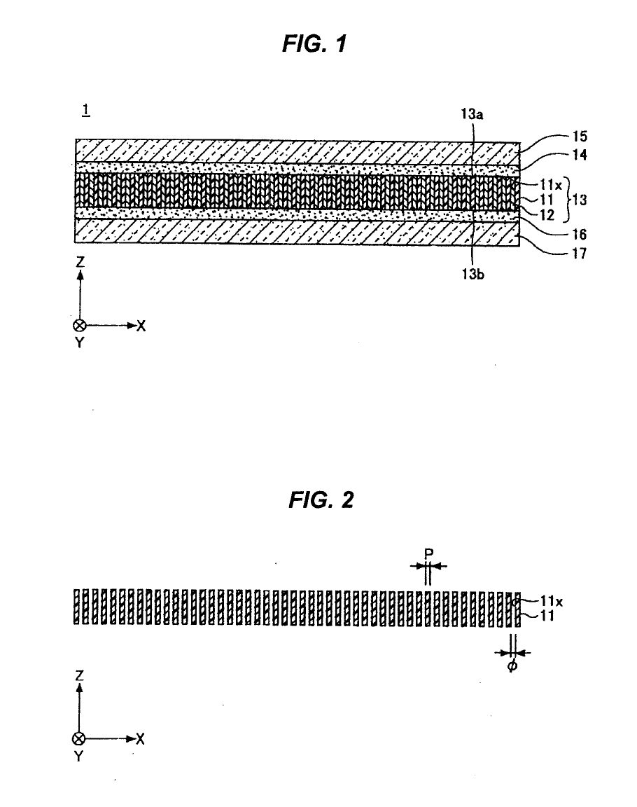

First, the structure of a base member according to a first embodiment will be described. FIG. 1 is a sectional view of the base member according to the first embodiment. In FIG. 1, the X direction is the direction that is parallel with one surface 13a of a core layer 13, the Y direction is the direction that is perpendicular to the X direction in the one surface 13a of the core layer 13, and the Z direction is the direction that is perpendicular to the X direction and the Y direction, that is, the thickness direction of the base member 1. These definitions also apply to the other drawings.

As shown in FIG. 1, the base member 1 according to the first embodiment is generally composed of the core layer 13, bonding layers 14 and 16, and silicon layers 15 and 17.

The base member 1 is a flat-plate-like base member for manufacture of a wiring substrate. For example, the base member 1 has a square plan shape, in which case each of the width (i.e., the length in the X direction) and the depth (i.e., the length in the Y direction) is about 200 mm. Alternatively, the base member 1 may have a circular plan shape, in which case the diameter of the base member 1 is 6 inches, 8 inches, 12 inches, or the like. The thickness (i.e., the length in the Z direction) of the base member 1 is about 140 to 500 μm, for example.

The core layer 13 has a plate-like body 11 made of aluminum oxide and plural linear conductors 12 (vias) which penetrate through the plate-like body 11 in its thickness direction. The linear conductors 12 are formed by charging a metal material into many through-holes 11x which penetrate through the plate-like body 11 in its thickness direction (Z direction) over its entire area.

One end face of each linear conductor 12 is exposed in the one surface 13a of the core layer 13 and the other end face is exposed in the other surface 13b of the core layer 13. The linear conductors 12 are formed approximately parallel with each other approximately at regular intervals over almost the entire area of the plate-like body 11. For example, each linear conductor 12 is circular in a plan view and about 30 to 2,000 nm in diameter. The term “plan view” means a view that is obtained when a subject member is seen from the Z direction in FIG. 1.

It is preferable that the linear conductors 12 be formed so densely that the interval between adjoining linear conductors 12 is smaller than their diameter. However, no particular limitations are imposed on the arrangement form of the linear conductors 12; they may be arranged in hexagonal form or grid form. Example metal materials of the linear conductors 12 are silver (Ag), copper (Cu), and nickel (Ni).

The silicon layer 15 is formed on the surface 13a of the core layer 13 by the bonding layer 14. The silicon layer 17 is formed on the surface 13b of the core layer 13 by the bonding layer 16. For example, each of the bonding layers 14 and 16 is made of adhesive film having an epoxy resin or the like as the main component. Alternatively, each of the bonding layers 14 and 16 may be made of an inorganic adhesive such as low-melting-point glass. For example, the thickness of each of the bonding layers 14 and 16 is about 10 μm. For example, the thickness of each of the silicon layers 15 and 17 is about 20 to 100 μm.

An insulating layer may be formed on the surface of each of the silicon layers 15 and 17. The insulating layer may be a thermal oxide film (SiO₂) or a layer made of benzocyclobutene (BCB), polybenzoxazole (PBO), polyimide (PI), or the like. The structure of the base member 1 according to the embodiment has been described above.

Next, a manufacturing method of the base member 1 according to the first embodiment will be described. FIGS. 2-5 are sectional views illustrating a manufacturing process of the base member 1 according to the first embodiment.

First, in the step shown in FIG. 2, a flat plate made of aluminum (Al) is prepared and a plate-like body 11 which is made of aluminum oxide and through which many through-holes 11x are formed is formed from the prepared flat plate by anodic oxidation. The size of the plate-like body 11 can be determined arbitrarily. For example, where silicon wafers will be used as the silicon layers 15 and 17 in a later step, the plate-like body 11 may have a circular shape so as to conform to those silicon wafers in shape. For example, the thickness (in the Z direction) of the plate-like body 11 is about 50 to 1,000 μm.

For example, each through-hole 11x is circular in a plan view, in which case its diameter φ may be 30 to 2,000 nm. It is preferable that the through-holes 11x be formed so densely that the interval P between adjoining through-holes 11x is smaller than their diameter φ. However, no particular limitations are imposed on the arrangement form of the through-holes 11x; they may be arranged in hexagonal form or grid form.

The anodic oxidation is a method in which a flat plate made of aluminum (Al) as an anode is immersed in an electrolytic solution (preferably an aqueous solution of sulfuric acid) and current is caused to flow between the flat plate and a cathode electrode made of platinum (Pt) or the like which are opposed to each other (a pulse voltage is applied). As a result, a plate-like body 11 (aluminum anodic oxidation film) is formed which is made of aluminum oxide and through which many through-holes 11x are formed.

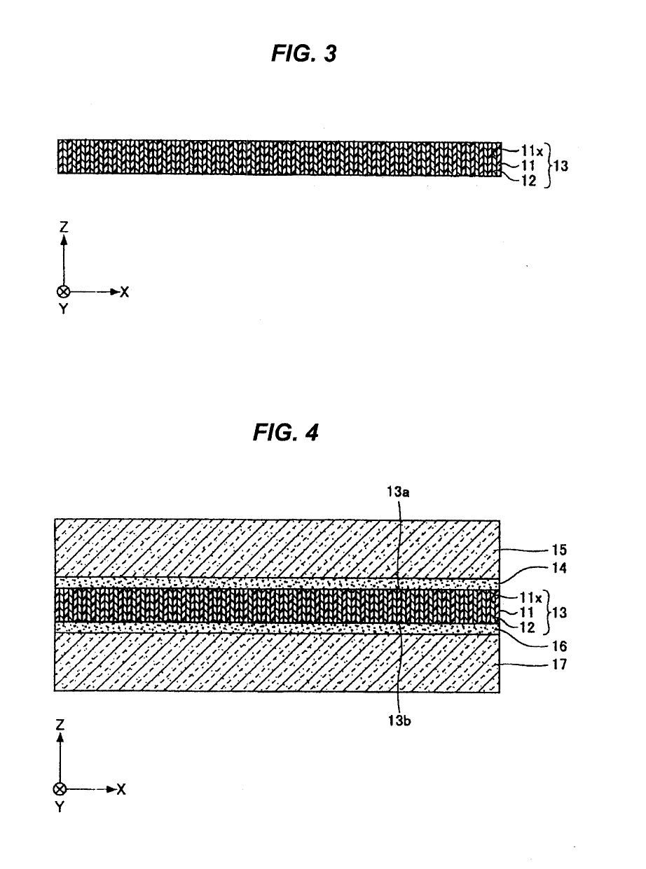

Then, in the step shown in FIG. 3, linear conductors 12 are formed by filling the through-holes 11x of the plate-like body 11 with a metal material. A core layer 13 is thus formed. For example, the linear conductors 12 are formed by filling the through-holes 11x with a conductive paste containing silver (Ag), copper (Cu), or the like.

Alternatively, where copper (Cu) is used as the metal material, linear conductors 12 may be formed by forming a seed layer on the surfaces of the plate-like body 11 (including the inner wall surfaces of the through-holes 11x) by electroless copper plating and filling the through-holes 11x with copper by electrolytic copper plating which uses the seed layer as an electricity supply layer. As a further alternative, linear conductors 12 may be formed by filling the through-holes 11x with copper merely by electroless copper plating.

If necessary, both surfaces of the resulting structure may be planarized by polishing by mechanical polishing, chemical mechanical polishing (CMP), or the like to expose both end faces of each linear conductor 12 in the surfaces of the plate-like body 11. In this manner, a core layer 13 is formed in which the linear conductors 12 having a very small diameter penetrate through the plate-like body 11 in its thickness direction and are arranged at a high density.

Then, in the step shown in FIG. 4, a silicon layer 15 is formed on one surface 13a of the core layer 13 by a bonding layer 14 and silicon layer 15 is formed on the other surface 13b of the core layer 13 by a bonding layer 16. For example, each of the silicon layers 15 and 17 is a silicon wafer of 6 inches (about 150 mm), 8 inches (about 200 mm), or 12 inches (about 300 mm). For example, the thickness of each silicon wafer is 0.625 (in the case of 6 inches), 0.725 mm (in the case of 8 inches), or 0.775 mm (in the case of 12 inches). For example, each of the bonding layers 14 and 16 is made of adhesive film having an epoxy resin or the like as the main component. Alternatively, each of the bonding layers 14 and 16 may be made of an inorganic adhesive such as low-melting-point glass. For example, the thickness of each of the bonding layers 14 and 16 is about 10 μm.

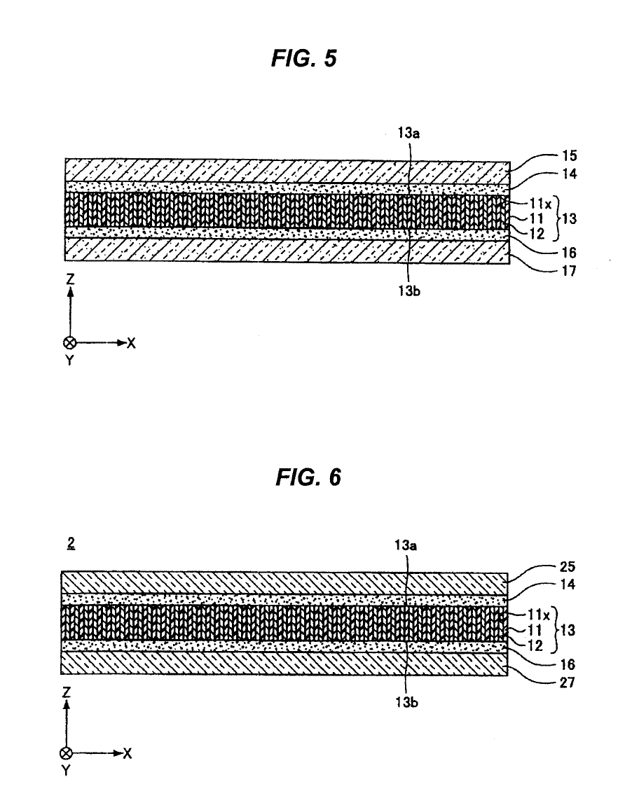

Finally, in the step shown in FIG. 5, the silicon layers 15 and 17 are thinned using a backside grinder, for example. For example, the thickness of each of thinned silicon layers 15 and 17 is set at about 20 to 100 μm. Where the thickness of each of thinned silicon layers 15 and 17 is set less than about 100 μm, in manufacturing a wiring substrate from the base member 1, through-holes penetrating through each of the silicon layers 15 and 17 can be formed easily and an electricity supply layer to be used for filling the thus-formed through-holes by electrolytic plating can be formed easily. The thickness of each of thinned silicon layers 15 and 17 may be set less than 20 μm as long as a finally produced base member 1 is given sufficient mechanical strength.

The silicon layers 15 and 17 may be formed on the core layer 13 by the respective bonding layers 14 and 16 after being thinned. However, since thinned silicon layers 15 and 17 are difficult to handle, it is preferable to thin the silicon layers 15 and 17 after they are formed on the core layer 13 by the respective bonding layers 14 and 16.

After the step shown in FIG. 5, an insulating layer may be formed on the surface of each of the silicon layers 15 and 17. The insulating layer may be a thermal oxide film (SiO₂) or a layer made of benzocyclobutene (BCB), polybenzoxazole (PBO), polyimide (PI), or the like. For example, a thermal oxide film (SiO₂) can be formed by a wet thermal oxidation method in which the temperature in the vicinity of the surface of the core layer 13 is set at 1,000° C. or higher, for example. The thickness of the thermal oxide film may be about 1 to 2 μm.

For example, a layer of benzocyclobutene (BCB), polybenzoxazole (PBO), or polyimide (PI) can be formed by spin coating or the like. The thickness of a layer of benzocyclobutene (BCB), polybenzoxazole (PBO), or polyimide (PI) may be set at about 2 to 30 μm. However, where a thermal oxide film (SiO₂) is formed, attention should be paid to the heat resistance of the bonding layers 14 and 16. That is, where each of the bonding layers 14 and 16 is made of an organic adhesive such as adhesive film having an epoxy resin as the main component, it is necessary to form a thermal oxide film by CVD (chemical vapor deposition). Insulating layers may be formed in a process of manufacturing a wiring substrate from the base member 1. The manufacturing method of the base member 1 according to the first embodiment has been described above.

The base member 1 may be shipped as a product(s) either in the state of FIG. 5 or after being cut into members having a prescribed shape.

According to the above-described first embodiment, since the silicon layers 15 and 17 are formed on the two surfaces of the core layer 13 which is formed with the many linear conductors 12 via the bonding layers 14 and 16, respectively, the mechanical strength of the base member 1 can be made much higher than that of conventional ones (having only the core layer 13). As a result, the base member 1 can be handled much more easily while it is transported or handled in a manufacturing process and the problem that a crack may develop in a base member while it is transported or handled in a manufacturing process and like problems can be solved.

Since the silicon layers 15 and 17 are thinned (e.g., about 20 to 100 μm), via holes can easily be formed through them in a process of manufacturing a wiring substrate from the base member 1.

Since via holes and wiring patterns can be formed through or on the silicon layers 15 and 17 in a process of manufacturing a wiring substrate from the base member 1 by a semiconductor process, ultra-fine via holes and wiring patterns can be formed.

The above advantages can also be obtained by a structure in which a silicon layer is formed on only one of the surfaces 13a and 13b of the core layer 13 via a bonding layer and no layers are formed on the other surface (i.e., the linear conductors 12 are exposed in the other surface).

In a first modification of the first embodiment, glass layers are formed in place of the silicon layers 15 and 17. In the first modification of the first embodiment, constituent elements having the same ones in the first embodiment will not be described in detail.

FIG. 6 is a sectional view of a base member 2 according to the first modification of the first embodiment. As shown in FIG. 2, the base member 2 according to the first modification of the first embodiment is different from the base member 1 according to the first embodiment (see FIG. 1) in that the silicon layers 15 and 17 are replaced by glass layers 25 and 27, respectively.

For example, the material of the glass layers 25 and 27 is borosilicate glass. Borosilicate glass is glass whose main components are boron oxide (B₂O₃) and silica (SiO₂), and has a thermal expansion coefficient of about 3 to 6 ppm/° C. which is close to the thermal expansion coefficient of silicon. For example, the thickness of each of the glass layers 25 and 27 is set at about 20 to 100 μm.

Where the thickness of each of glass layers 25 and 27 is set less than about 100 μm, in manufacturing a wiring substrate from the base member 2, through-holes penetrating through each of the glass layers 25 and 27 can be formed easily and an electricity supply layer to be used for filling the thus-formed through-holes by electrolytic plating can be formed easily. The thickness of each of glass layers 25 and 27 may be set less than 20 μm as long as a finally produced base member 2 is given sufficient mechanical strength.

The base member 2 can be manufactured by a manufacturing process which is approximately the same as the manufacturing process of the base member 1. Steps corresponding to the steps of FIGS. 4 and 5 may be such that glass layers 25 and 27 are formed on the two surfaces of the core layer 13 via bonding layers 14 and 15, respectively, and thinned thereafter or glass layers 25 and 27 thinned in advance are formed on the two surfaces of the core layer 13 via bonding layers 14 and 15, respectively. The reason why the glass layers 25 and 27 can be thinned (e.g., to about 20 to 100 μm) in advance is that they can be handled relatively easily even in a thinned state in contrast to the case of the silicon layers 15 and 17.

Since the glass layers 25 and 27 are insulators in contrast to the silicon layers 15 and 17, it is not necessary to form insulating layers in a manufacturing process of the base member 2 or a process of manufacturing a wiring substrate from the base member 2. Therefore, the manufacturing process of the base member 2 or the process of manufacturing a wiring substrate from the base member 2 can be simplified.

The first modification of the first embodiment provides the same advantages as the first embodiment does because the glass layers 25 and 27 are formed on the two surfaces of the core layer 13 which is formed with the many linear conductors 12 via the bonding layers 14 and 16, respectively. The first modification of the first embodiment provides another advantage that the manufacturing cost of the base member 2 can be made lower because the glass layers 25 and 27 are less expensive than the silicon layers 15 and 17.

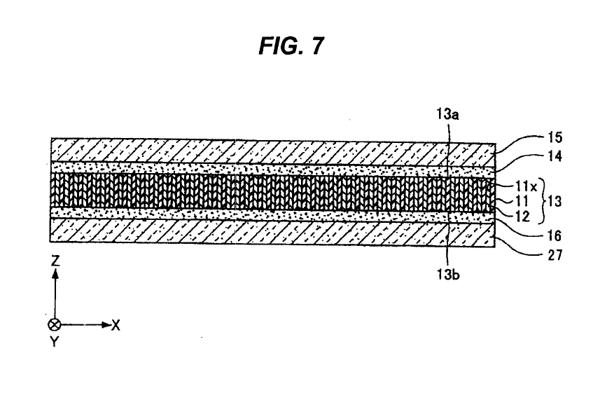

The above advantages can also be obtained by a structure in which a glass layer is formed on only one of the surfaces 13a and 13b of the core layer 13 via a bonding layer and no layers are formed on the other surface (i.e., the linear conductors 12 are exposed in the other surface). Further, the above advantages can also be obtained by a structure in which a silicon layer is formed on one surface of a core layer via a bonding layer and a glass layer is formed on another surface of the core layer via a bonding layer, as shown in FIG. 7, being a sectional view of a base member according to a second modification of the first embodiment.

In a second embodiment, a wiring layer is formed on each of the two surfaces 13a and 13b of the core layer 13. In the second embodiment, constituent elements having the same ones in the first embodiment will not be described in detail.

FIG. 8 is a sectional view of a base member 3 according to the second embodiment. As shown in FIG. 8, the base member 3 according to the second embodiment is different from the base member 1 according to the first embodiment (see FIG. 1) in that a wiring layer 31 is formed on the one surface 13a of the core layer 13 and a wiring layer 32 is formed on the other surface 13b.

The wiring layer 31 is formed on the one surface 13a of the core layer 13 and covered with a bonding layer 14. Each pattern of the wiring layer 31 is electrically connected to the end faces, exposed in the surface 13a, of plural linear conductors 12. The wiring layer 32 is formed on the other surface 13b of the core layer 13 and covered with a bonding layer 16. Each pattern of the wiring layer 32 is electrically connected to the end faces, exposed in the surface 13b, of plural linear conductors 12. Each pattern of the wiring layer 32 is formed so as to approximately coextend with the corresponding pattern of the wiring layer 31 in a plan view, and is electrically connected to the latter by plural linear conductors 12.

For example, the material of the wiring layers 31 and 32 is copper (Cu). Alternatively, each of the wiring layers 31 and 32 may be formed by laying a titanium (Ti) layer and a copper (Cu) layer in this order on the surface 13a or 13b. For example, the thickness of each of the wiring layers 31 and 32 is set at about 1 to 20 μm.

Where each of the wiring layers 31 and 32 is formed by laying a titanium layer and a copper layer in this order, they are laid on the surface 13a or 13b of the core layer 13 by sputtering or the like. An additional copper layer can be formed by electrolytic plating using the already formed titanium layer and copper layer as an electricity supply layer.

Since the base member 3 is to be used for manufacturing a wiring substrate, pattern shapes etc. of the wiring layers 31 and 32 are determined according to a specification of a manufacturer of the wiring substrate. That is, whereas the base members 1 and 2 are general-purpose products, the base member 3 is a semi-custom product.

Although the wiring layers 31 and 32 are formed on the respective surfaces 13a and 13b of the core layer 13, the second embodiment provides the same advantages as the first embodiment does. The second embodiment provides another advantage that because of the presence of the wiring layers 31 and 32 the mechanical strength of the base member 3 can be made higher than that of the base members 1 and 2.

As in the first modification of the first embodiment, glass layers 25 and 27 may be used in place of the silicon layers 15 and 17. Where the glass layers 25 and 27 are used, the manufacturing cost of the base member can be made lower because they are less expensive than the silicon layers 15 and 17. If alignment marks are formed in the wiring layers 31 and 32, they are seen through the bonding layer 14 and the glass layer 25 or the bonding layer 16 and the glass layer 27 and hence the level of alignment can be increased.

The above advantages can also be obtained by a structure in which both of a wiring layer and a silicon layer (or glass layer) are formed on only one of the surfaces 13a and 13b of the core layer 13 via a bonding layer and the same layers as in the base member 1 or 2 (see FIG. 1 or 6) are formed on the other surface.

A first modification of the second embodiment is directed to a case that the wiring layers have a pseudo-coaxial structure. In the first modification of the second embodiment, constituent elements having the same ones in the above-described embodiments will not be described in detail.

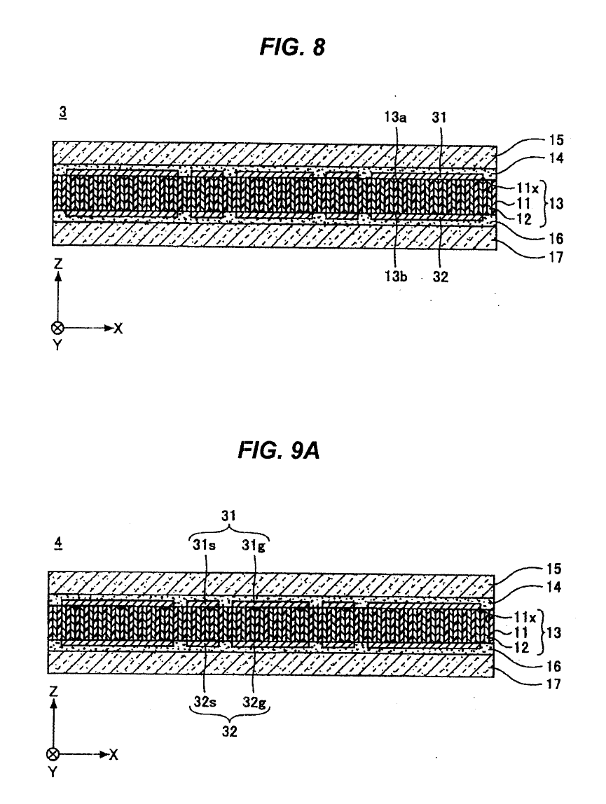

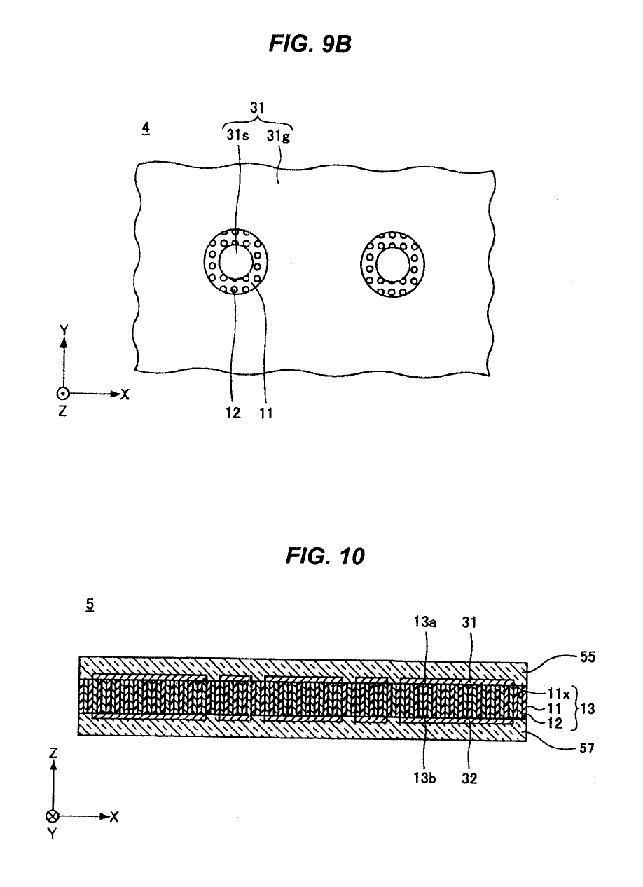

FIG. 9A is a sectional view of a base member 4 according to the first modification of the second embodiment. FIG. 9A is a partial plan view of the base member 4 according to the first modification of the second embodiment. As shown in FIGS. 9A and 9B, the base member 4 according to the first modification of the second embodiment is different from the base member 3 according to the second embodiment (see FIG. 8) in that wiring layers 31 and 32 have a pseudo-coaxial structure.

As for the wiring layers 31 and 32, GND (ground) lines 31g and 32g and plural linear conductors 12 connecting them are disposed around each set of signal lines 31s and 32s and plural linear conductors 12 connecting them with a prescribed interval. Each pair of signal lines 31s and 32s are lines to transmit a signal when a wiring substrate is formed using the base member 4. The GND lines 31g and 32g are lines to be electrically connected to a reference potential (GND potential) when a wiring substrate is formed using the base member 4.

Since the base member 4 is to be used for manufacturing a wiring substrate, pattern shapes etc. of the wiring layers 31 and 32 are determined according to a specification of a manufacturer of the wiring substrate. That is, like the base member 3, the base member 4 is a semi-custom product.

As described above, each set of signal lines 31s and 32s and plural linear conductors 12 connecting them and the GND lines 31g and 32g and the plural linear conductors 12 connecting them which are disposed around the set of signal lines 31s and 32s and plural linear conductors 12 connecting them constitute a structure that is equivalent to a coaxial line. As a result, an advantage is obtained that the signal lines 31s and 32s and the plural linear conductors 12 connecting them are shielded from external noise.

The GND lines 31g and 32g and the plural linear conductors 12 connecting them exists between adjoining sets of signal lines 31s and 32s and plural linear conductors 12 connecting them. Therefore, the degree of electrical coupling (capacitive coupling) between adjoining sets of signal lines 31s and 32s and plural linear conductors 12 connecting them can be reduced, and hence each set of signal lines 31s and 32s and plural linear conductors 12 connecting them is prevented from becoming a noise source.

As in the first modification of the first embodiment, glass layers 25 and 27 may be used in place of the silicon layers 15 and 17. Where the glass layers 25 and 27 are used, the manufacturing cost of the base member can be made lower because they are less expensive than the silicon layers 15 and 17. If alignment marks are formed in the wiring layers 31 and 32, they are seen through the bonding layer 14 and the glass layer 25 or the bonding layer 16 and the glass layer 27 and hence the level of alignment can be increased.

In a second modification of the second embodiment, glass layers are formed directly on the respective surfaces of the core layer. In the second modification of the second embodiment, constituent elements having the same ones in the above-described embodiments will not be described in detail.

FIG. 10 is a sectional view of a base member 5 according to the second modification of the second embodiment. As shown in FIG. 10, the base member 5 according to the second modification of the second embodiment is different from the base member 3 according to the second embodiment (see FIG. 8) in that the bonding layers 14 and 16 are omitted and the silicon layers 15 and 17 are replaced by glass layers 55 and 57.

More specifically, in the base member 5, the glass layer 55 is formed directly on the surface 13a of the core layer 13 and the glass layer 57 is formed directly on the surface 13b of the core layer 13. The wiring layers 31 and 32 are covered with the respective glass layers 55 and 57. For example, the thickness of each of the glass layers 55 and 57 is set at about 20 to 100 μm.

For example, the material of the glass layers 55 and 57 is low-melting-point glass, an example of which is a type formed by adding bismuth, indium, or the like to borosilicate glass to lower the melting point.

The glass layers 55 and 57 are formed in the following manner. For example, after wiring layers 31 and 32 are formed on the respective surfaces 13a and 13b of the core layer 13, low-melting-point glass paste is applied to the surfaces 13a and 13b of the core layer 13 so as to cover the wiring layers 31 and 32 and then fired at about 450° C., for example. Alternatively, solid low-melting-point glass members are placed on the respective surfaces 13a and 13b of the core layer 13, softened by heating them at about 450° C., for example, while pressing them, and then solidified.

Since the base member 5 is to be used for manufacturing a wiring substrate, pattern shapes etc. of the wiring layers 31 and 32 are determined according to a specification of a manufacturer of the wiring substrate. That is, like the base members 3 and 4, the base member 5 is a semi-custom product.

Although the glass layers 55 and 57 are formed directly on the respective surfaces 13a and 13b of the core layer 13 which is formed with the many linear conductors 12, the second modification of the second embodiment provides the same advantages as the second embodiment does. The second modification of the second embodiment provides another advantage that the degrees of unmatching between the thermal expansion coefficients of the constituent members can be reduced because the base member 5 is composed of the core layer 13, the wiring layers 31 and 32, and the glass layers 55 and 57 and no resin bonding layers are used whose thermal expansion coefficient is several tens of parts per million per degree centigrade.

The heat resistance of the base member 5 can be made high because no resin bonding layers are used which are low in heat resistance.

The manufacturing cost of the base member 5 can be made lower because the glass layers 55 and 57 are less expensive than the silicon layers 15 and 17.

If alignment marks are formed in the wiring layers 31 and 32, they are seen through the glass layers 55 and 57 and hence the level of alignment can be increased.

The above advantages can also be obtained by a structure in which a wiring layer and a glass layer are formed on only one of the surfaces 13a and 13b of the core layer 13 and no layers are formed on the other surface (i.e., the linear conductors 12 are exposed in the other surface). The above advantages can also be obtained by a structure in which the wiring layers 31 and 32 are formed on the respective surfaces 13a and 13b of the core layer 13 and a glass layer is formed on only one of the surfaces 13a and 13b of the core layer 13 so as to cover the wiring layer 31 or 32.

In the structure in which the wiring layers 31 and 32 are formed on the respective surfaces 13a and 13b of the core layer 13 and a glass layer is formed so as to cover only one of the wiring layers 31 and 32, the following additional layers may be formed. That is, an insulating layer made of an epoxy insulative resin or the like is formed so as to cover the wiring layer 31 or 32 that is not covered with a glass layer, and another wiring layer is formed on the insulating layer so as to be electrically connected to the underlying wiring layer 31 or 32 by lines formed through the insulating layer.

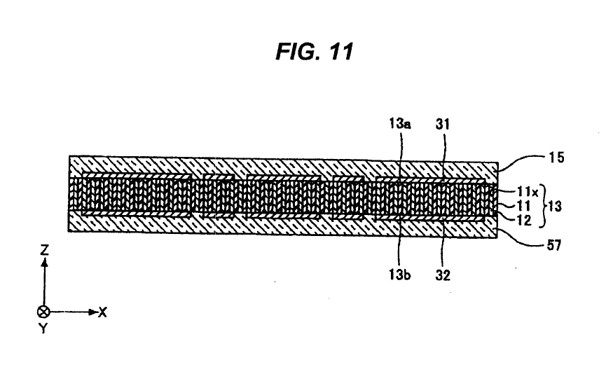

Furthermore, the glass layers 55 and 57 may be formed on the respective surfaces 13a and 13b of the core layer 13 directly (i.e., neither of the wiring layers 31 and 32 is formed). This is a structure in which the wiring layers 31 and 32 are omitted from the base member 5 shown in FIG. 10). Furthermore, the silicon layer 15 maybe formed in place of the glass layers 55, as shown in FIG. 11, being a sectional view of a base member according to a third modification of the second embodiment.

In a third embodiment, wiring layers and an insulating layer are provided on each of the two surfaces of the core layer. In the third embodiment, constituent elements having the same ones in the above-described embodiments will not be described in detail.

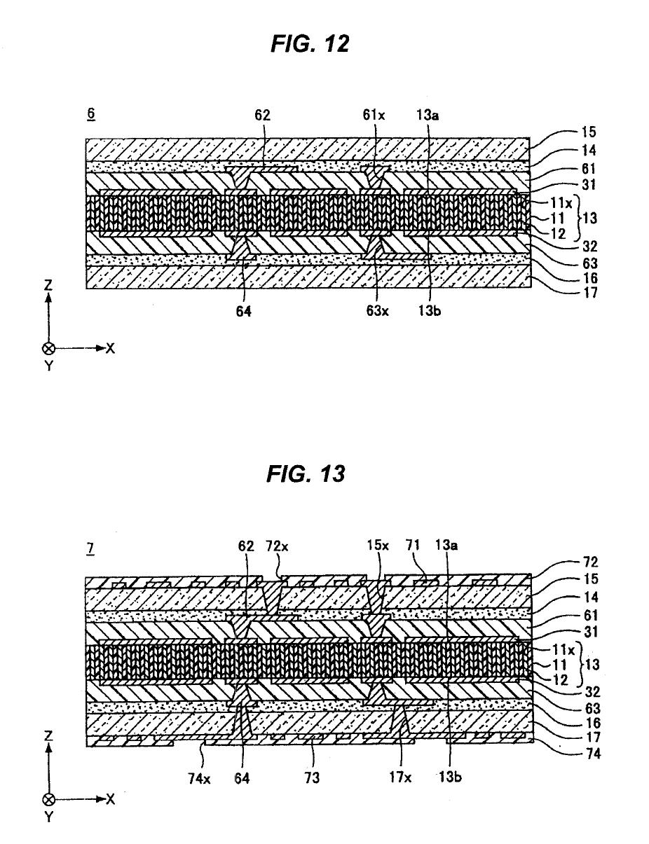

FIG. 12 is a sectional view of a base member 6 according to the third embodiment. As shown in FIG. 12, the base member 6 according to the third embodiment is different from the base member 3 according to the second embodiment (see FIG. 8) in that a wiring layer 31, an insulating layer 61, and a wiring layer 62 are provided between the one surface 13a of the core layer 13 and the bonding layer 14 and that a wiring layer 32, an insulating layer 63, and a wiring layer 64 are provided between the other surface 13a and the bonding layer 16.

The insulating layer 61 is formed on the surface 13a of the core layer 13 so as to cover the wiring layer 31. For example, the material of the insulating layer 61 is an insulative resin having an epoxy resin as the main component. For example, the thickness of the insulating layer 61 is set at about 10 to 30 μm.

The wiring layer 62 is formed on the surface of the insulating layer 61. The wiring layer 62 includes via lines formed inside via holes 61x which penetrate through the insulating layer 61 and thereby expose surface portions of the wiring layer 31 and wiring patterns formed on the surface of the insulating layer 61. The wiring patterns are patterned so as to have prescribed plan shapes. Each via hole 61x is a truncated-cone-shaped through-hole in which the opening on the side of the bonding layer 14 is wider than the opening on the side of the wiring layer 31. The via lines are formed in the respective via holes 61x.

Each portion of the wiring layer 62 is electrically connected to a corresponding portion, exposed by the via hole 61x, of the wiring layer 31. For example, the material of the wiring layer 62 is a conductive material having copper (Cu) as the main component. For example, the thickness of the wiring patterns of the wiring layer 62 is set at about 10 to 20 μm. The wiring layer 62 is covered with the bonding layer 14.

The insulating layer 63 is formed on the surface 13b of the core layer 13 so as to cover the wiring layer 32. For example, the material of the insulating layer 63 is an insulative resin having an epoxy resin as the main component. For example, the thickness of the insulating layer 63 is set at about 10 to 30 μm.

The wiring layer 64 is formed on the surface of the insulating layer 63. The wiring layer 64 includes via lines formed inside via holes 63x which penetrate through the insulating layer 63 and thereby expose surface portions of the wiring layer 32 and wiring patterns formed on the surface of the insulating layer 63. The wiring patterns are patterned so as to have prescribed plan shapes. Each via hole 63x is a truncated-cone-shaped through-hole in which the opening on the side of the bonding layer 16 is wider than the opening on the side of the wiring layer 32. The via lines are formed in the respective via holes 63x.

Each portion of the wiring layer 64 is electrically connected to a corresponding portion, exposed by the via hole 63x, of the wiring layer 32. For example, the material of the wiring layer 64 is a conductive material having copper (Cu) as the main component. For example, the thickness of the wiring patterns of the wiring layer 64 is set at about 10 to 20 μm. The wiring layer 64 is covered with the bonding layer 16.

Since the base member 6 is to be used for manufacturing a wiring substrate, pattern shapes etc. of the wiring layers 31, 32, 62, and 64 are determined according to a specification of a manufacturer of the wiring substrate. That is, like the base members 3-5, the base member 6 is a semi-custom product.

Although the wiring layers 31 and 62 and the insulating layer 14 are provided on the surface 13a of the core layer 13 and the wiring layers 32 and 64 and the insulating layer 16 are provided on the surface 13b of the core layer 13, the third embodiment provides the same advantages as the first embodiment does. The third embodiment provides another advantage that it enables pitch conversion between the silicon layers 15 and 17 using the wiring layers 31, 32, 62, and 64 and the insulating layers 61 and 63.

As in the first modification of the first embodiment, glass layers 25 and 27 may be used in place of the silicon layers 15 and 17. Where the glass layers 25 and 27 are used, the manufacturing cost of the base member can be made lower because they are less expensive than the silicon layers 15 and 17. If alignment marks are formed in the wiring layers 62 and 64, they are seen through the bonding layer 14 and the glass layer 25 or the bonding layer 16 and the glass layer 27 and hence the level of alignment can be increased.

Wiring layers and an insulating layer may be provided on only one of the surfaces 13a and 13b of the core layer 13.

A structure is possible in which wiring layers and an insulating layer are provided on only one of the surfaces 13a and 13b of the core layer 13 and the same layers as in the base member 3 (see FIG. 8), for example, are formed on the other surface.

A description will be made of an example wiring substrate which uses the base member 6 according to the third embodiment. FIG. 13 is a sectional view of a wiring substrate 7 which uses the base member 6 according to the third embodiment.

As shown in FIG. 13, the wiring substrate 7 is configured in such a manner that a wiring layer 31, an insulating layer 61, a wiring layer 62, a bonding layer 14, a silicon layer 15, a wiring layer 71, and a solder resist layer 72 are provided in this order on one surface 13a of a core layer 13 and a wiring layer 32, an insulating layer 63, a wiring layer 64, a bonding layer 16, a silicon layer 17, a wiring layer 73, and a solder resist layer 74 are provided in this order on the other surface 13b of the core layer 13. Insulating layers (not shown) are formed on the surfaces (including the inner wall surfaces of via holes 15x and 17x) of the silicon layers 15 and 17.

For example, the solder resist layers 72 and 74 are made of an insulative resin having an epoxy resin as the main component, and the wiring layers 71 and 73 are made of a conductive material having copper (Cu) as the main component.

The wiring layer 71 is formed on the surface of the silicon layer 15. The wiring layer 71 includes via lines formed inside the via holes 15x which penetrate through the silicon layer 15 and thereby expose surface portions of the wiring layer 62 and wiring patterns formed on the surface of the silicon layer 15. The wiring patterns are patterned so as to have prescribed plan shapes. Part of the wiring patterns of the wiring layer 71 are exposed by openings 72x of the solder resist layer 72, and function as, for example, pads for electrical connection to a semiconductor device.

The wiring layer 73 is formed on the surface of the silicon layer 17. The wiring layer 73 includes via lines formed inside the via holes 17x which penetrate through the silicon layer 17 and thereby expose surface portions of the wiring layer 64 and wiring patterns formed on the surface of the silicon layer 17. The wiring patterns are patterned so as to have prescribed plan shapes. Part of the wiring patterns of the wiring layer 73 are exposed by openings 74x of the solder resist layer 74, and function as, for example, pads for electrical connection to such a board as a motherboard. Alternatively, that part of the wiring patterns of the wiring layer 73 which are exposed by openings 74x may be used as pads for electrical connection to a semiconductor device. The wiring substrate 7 can be manufactured by known manufacturing processes.

As is understood from the above description, the wiring substrate 7 can be manufactured by a known manufacturing process after acquiring the base member 6. Furthermore, a semiconductor package can be manufactured by mounting a semiconductor device on the wiring substrate 7.

Since the wiring layers 71 and 73 can be formed on the respective silicon layers 15 and 17 by a semiconductor process, they can be given ultra-fine via holes and wiring patterns. The line width and the interval of the wiring patterns of the wiring layers 71 and 73 can each be set equal to about 1 to 10 μm, for example.

A wiring substrate or a semiconductor package can also be manufactured by using each of the base members 1-5.

Although the preferred embodiments and their modifications have been described above, the invention is not limited to them. Change and replacement can be made in the above embodiments and modifications in various manners without departing from the scope as defined by the claims. For example, features of the above embodiments and modifications may be combined as appropriate.

Another mode is possible in which a silicon layer is formed on one of the surfaces 13a and 13b of the core layer 13 via a bonding layer and a glass layer is formed on the other surface of the core layer 13 via a bonding layer (or directly, that is, without interposition of a bonding layer). Even this mode can make the mechanical strength of the base member much higher than that of a conventional one (only the core layer 13).

1. A base member comprising:
a core layer including:
a plate-like body, made of aluminum oxide; and
plural linear conductors, which penetrate through the plate-like body in a thickness direction of the plate-like body;
a bonding layer, formed on at least one of a first surface and a second surface of the core layer; and
a silicon layer or a glass layer, formed on the bonding layer.

2. The base member according to claim 1, wherein:
a silicon layer is formed on the bonding layer that is formed on the first surface; and
a glass layer is formed on the bonding layer that is formed on the second surface.

3. The base member according to claim 1, further comprising
a wiring layer which is formed on the at least one of the first surface and the second surface so as to be electrically connected to part of the plural linear conductors and to be covered with the bonding layer.

4. A base member comprising:
a core layer including:
a plate-like body, made of aluminum oxide; and
plural linear conductors, which penetrate through the plate-like body in a thickness direction of the plate-like body; and
a first wiring layer, which is electrically connected to part of the plural linear conductors, and is formed on at least one of a first surface and a second surface of the core layer;
an insulating layer, covering the first wiring layer;
a second wiring layer, electrically connected to the first wiring layer by lines formed through the insulating layer;
a bonding layer, covering the second wiring layer; and
a silicon layer or a glass layer, formed on the bonding layer.

5. A base member comprising:
a core layer including:
a plate-like body, made of aluminum oxide; and
plural linear conductors, which penetrate through the plate-like body in a thickness direction of the plate-like body; and
a glass layer, formed on at least one of a first surface and a second surface of the core layer.

6. The base member according to claim 5, further comprising
a first wiring layer, which is formed on the first surface so as to be electrically connected to part of the plural linear conductors and to be covered with the glass layer.

7. The base member according to claim 6, further comprising:
a second wiring layer, which is formed on the second surface so as to be electrically connected to the wiring layer by the part of the plural linear conductors;
an insulating layer, covering the second wiring layer;
a third wiring layer, electrically connected to the second wiring layer by lines formed through the insulating layer.

8. The base member according to claim 3, wherein
the wiring layer includes a signal line and a ground line which surrounds the signal line in a plan view.

9. The base member according to claim 4, wherein
the wiring layer includes a signal line and a ground line which surrounds the signal line in a plan view.

10. The base member according to claim 6, wherein
the first wiring layer includes a signal line and a ground line which surrounds the signal line in a plan view.

11. The base member according to claim 7, wherein
at least one of the first wiring layer and the second wiring layer includes a signal line and a ground line which surrounds the signal line in a plan view.

12. The base member according to claim 2, further comprising
a wiring layer which is formed on the at least one of the first surface and the second surface so as to be electrically connected to part of the plural linear conductors and to be covered with the bonding layer.
